(19) United States
(12) Patent Application Publication
(10) Pub. No.: US 2023/0187363 A1
(43) Pub. Date: Jun. 15, 2023

(54) PACKAGING STRUCTURE AND MANUFACTURING METHOD THEREOF

(71) Applicant: JCET GROUP CO., LTD., Wuxi City (CN)

(72) Inventors: YAOJIAN LIN, Wuxi City (CN); SHUO LIU, Wuxi City (CN); DANFENG YANG, Wuxi City (CN); QINGYUN ZHOU, Wuxi City (CN); CHEN XU, Wuxi City (CN); CHENYE HE, Wuxi City (CN)

(21) Appl. No.: 18/077,209

(22) Filed: Dec. 7, 2022

(30) Foreign Application Priority Data
Dec. 9, 2021 (CN) 202111496539.7

(51) Int. Cl. H01L 23/538; H01L 25/10; H01L 23/31; H01L 23/498; H01L 21/48; H01L 21/56

(52) U.S. Cl. CPC H01L 23/5383; H01L 25/105; H01L 23/5384; H01L 23/3128; H01L 23/49811; H01L 21/4857; H01L 21/56

(57) ABSTRACT

The present invention provides a packaging structure and a manufacturing method thereof. The packaging structure includes a lower package and an upper package; wherein the lower package includes a prefabricated interconnected silicon core stack structure which includes a silicon interconnection layer, and the silicon interconnection layer includes a first surface and a second surface; a back-end redistribution stack layer and a first prefabricated redistribution stack layer are stacked on the first surface and in electrical connection; a passivation layer is disposed on the second surface; the silicon interconnection layer includes a silicon substrate and several first prefabricated conductive pillars, each first prefabricated conductive pillar includes a first end and a second end, the first end is exposed from the first surface, and the second end is exposed from a side of the passivation layer; and the upper package is disposed above the first prefabricated redistribution stack layer.

### TECHNICAL FIELD

The present invention relates to the field of semiconductor packaging technologies, and in particular to a packaging structure and a manufacturing method thereof.

### BACKGROUND

With the rapid development of high-speed computation and artificial intelligence, higher requirements are put forward on packaging of semiconductor chips and packages, especially for packaging substrates, which are usually required to have smaller line width/line spacing and better control of voltage drop. However, the line width/line spacing of the traditional laminated substrate wiring is usually about 15 μm/15 μm, which becomes increasingly incompetent to satisfy high-density packaging requirements for electronic components applied to high-speed computation and artificial intelligence.

In addition, the traditional laminated substrate technology is faced with greater challenges in the following aspects: 1) supply of stacked dielectric materials; 2) manufacturing cycle; 3) wiring with the line width/line spacing being less than 10 μm and yield control of the embedded chip; and 4) balance between thickness and hardness of the substrate.

Therefore, it is necessary to propose a new packaging structure and a manufacturing method thereof to overcome the problem that the traditional laminated substrates cannot satisfy the high-density packaging requirements for electronic components applied to high-speed computation and artificial intelligence due to thickness, line width line spacing and other factors.

### SUMMARY

An object of the present invention is to provide a packaging structure and a manufacturing method thereof, which can overcome detects of the traditional laminated substrates and satisfy high-density packaging requirements for electronic components.

In order to solve the above problem, technical solutions of the present invention provide a packaging structure. The packaging structure includes a lower package and an upper package disposed above the lower package, wherein the lower package and the upper package are electrically connected; the lower package includes a prefabricated interconnected silicon core stack structure and a first plastic packaging layer surrounding the periphery of the prefabricated interconnected silicon core stack structure; the prefabricated interconnected silicon core stack structure includes a silicon interconnection layer, and the silicon interconnection layer includes a first surface and a second surface facing away from each other; a back-end redistribution stack layer and a first prefabricated redistribution stack layer are stacked sequentially on the first surface and in electrical connection; a passivation layer is disposed on the second surface; the silicon interconnection layer includes a silicon substrate and a plurality of first prefabricated conductive pillars embedded in a plurality of through-silicon-vias of the silicon substrate, each first prefabricated conductive pillar includes a first end and a second end opposite to each other, the first end is exposed from the first surface, and the second end is exposed from a side of the passivation layer away from the second surface; and wherein the upper package is disposed above the first prefabricated redistribution stack layer, and is electrically connected to the first prefabricated redistribution stack layer.

As an optional technical solution, the packaging structure further includes a back-surface redistribution stack layer disposed below the prefabricated interconnected silicon core stack structure, wherein the back-surface redistribution stack layer is disposed at a side of the passivation layer away from the second surface, and is electrically connected to the silicon interconnection layer.

As an optional technical solution, an edge of the back-surface redistribution stack layer protrudes from an edge of the prefabricated interconnected silicon core stack structure and extends to be stacked on the first plastic packaging layer, and/or an edge of the passivation layer protrudes from an edge of the silicon interconnection layer and extends to be stacked on the first plastic packaging layer.

As an optional technical solution, the prefabricated interconnected silicon core stack structure further includes a second prefabricated redistribution stack layer that is disposed at a side of the passivation layer away from the second surface and is electrically connected to the second end of each of the first prefabricated conductive pillars in the silicon interconnection layer.

As an optional technical solution, the lower package further includes at least one first functional block and/or at least one second functional block; the at least one first functional block is embedded in a first base material layer of the first prefabricated redistribution stack layer; and the at least one second functional block is embedded in a second base material layer of the second prefabricated redistribution stack layer; wherein the upper package includes a chip and/or device package; in a thickness direction of the packaging structure, the at least one first functional block is stacked below the corresponding chip and/or device package; and the at least one second functional block is stacked below the corresponding chip and/or device package.

As an optional technical solution, the lower package further includes a prefabricated chip packaging layer, the prefabricated chip packaging layer includes a plurality of second prefabricated conductive pillars, a first chip and a prefabricated plastic packaging layer, the plurality of second prefabricated conductive pillars and the first chip are embedded in the prefabricated plastic packaging layer respectively, and the first plastic packaging layer further covers an outer side of the prefabricated plastic packaging layer; wherein the prefabricated chip packaging layer is disposed at a side of the first prefabricated redistribution stack layer away from the silicon interconnection layer; or the prefabricated chip packaging layer is disposed at a side of the second prefabricated redistribution stack layer away from the silicon interconnection layer, and the thickness of the prefabricated plastic packaging layer is 50 to 200 μm.

As an optional technical solution, the lower package further includes a third prefabricated redistribution stack layer that is disposed between the prefabricated chip packaging layer and the back-surface redistribution stack layer and is electrically connected to the prefabricated chip packaging layer and the back-surface redistribution stack layer.

As an optional technical solution, the prefabricated plastic packaging layer further includes a third functional block embedded therein, and the third functional block and the first chip are horizontally disposed side by side in the prefabricated plastic packaging layer.

As an optional technical solution, the lower package further includes a solder mask layer disposed between the first prefabricated redistribution stack layer and the upper package, wherein the elastic modulus or tensile elongation at break of the solder mask layer is the same as or different from the elastic modulus or tensile elongation at break of a dielectric layer in the first prefabricated redistribution stack layer.

As an optional technical solution, the packaging structure further includes a first redistribution stack layer that is disposed between the upper package and the lower package and is electrically connected to the upper package and the lower package.

As an optional technical solution, the packaging structure further includes a second redistribution stack layer and an interconnected chip packaging layer that are disposed between the lower package and the first redistribution stack layer; the second redistribution stack layer is disposed above the lower package; the interconnected chip packaging layer is disposed above the second redistribution stack layer; the interconnected chip packaging layer includes a plurality of conductive pillars, an interconnected chip and a second plastic packaging layer, the plurality of conductive pillars and the interconnected chip are embedded in the second plastic packaging layer respectively, two opposite ends of each conductive pillar are electrically connected to the first redistribution stack layer and the second redistribution stack layer, and the thickness of the second plastic packaging layer is 150 to 780 μm; and the interconnected chip includes an interconnected redistribution stack layer and a connection bump located above the interconnected redistribution stack layer, the connection bump is electrically connected to the first redistribution stack layer and the interconnected redistribution stack layer, the minimum line width/line spacing of the interconnected redistribution stack layer is less than 2 μm, and the interconnected redistribution stack layer includes at least one capacitor.

As an optional technical solution, the packaging structure further includes an auxiliary structure disposed at an edge and/or corner of the first redistribution stack layer.

As an optional technical solution, the silicon interconnection layer further includes a trench-type silicon capacitor electrically connected to the back-end redistribution stack layer.

As an optional technical solution, there are two or more prefabricated interconnected silicon core stack structures in the first plastic packaging layer, and two or more prefabricated interconnected silicon core stack structures are horizontally disposed side by side and all plastic-packaged by the first plastic packaging layer, wherein two or more prefabricated interconnected silicon core stack structures have same or different sizes.

As an optional technical solution, the lower package further includes a first prefabricated substrate, the first prefabricated substrate includes a third surface and a fourth surface facing away from each other, and the prefabricated interconnected silicon core stack structure is disposed on the third surface and/or the fourth surface and electrically connected to the first prefabricated substrate respectively, wherein the prefabricated interconnected silicon core stack structure and the prefabricated substrate constitute a first prefabricated unit, and the first prefabricated unit is packaged by the first plastic packaging layer to constitute the lower package.

As an optional technical solution, the lower package further includes an underfill layer filled between the prefabricated interconnected silicon core stack structure and the first prefabricated substrate.

As an optional technical solution, the lower package further includes a second prefabricated substrate and/or a third prefabricated substrate, the second prefabricated substrate and/or the third prefabricated substrate are horizontally disposed side by side with respect to the prefabricated interconnected silicon core stack structure respectively to constitute a second prefabricated unit, and the second prefabricated unit is packaged by the first plastic packaging layer to form the lower package, wherein base material layers of the second prefabricated substrate and the third prefabricated substrate may be made of the same or different materials.

The present invention further provides a manufacturing method or a packaging structure. The manufacturing method includes the following steps:

providing a silicon interconnection layer including a first surface and a second surface facing away from each other, wherein the silicon interconnection layer includes a silicon substrate, the silicon substrate includes a plurality of through-silicon-vias and first prefabricated conductive pillars embedded in the plurality of through-silicon-vias, each of the first prefabricated conductive pillars includes a first end and a second end opposite to each other, the first end is exposed from the first surface, and the second end is exposed from the second surface;

forming a back-end redistribution stack layer on the first surface, the first end of the first prefabricated conductive pillar being electrically connected to the back-end redistribution stack layer;

forming a passivation layer on the second layer and thinning the passivation layer, the second end of the first prefabricated conductive pillar being exposed from the passivation layer;

forming a first prefabricated redistribution stack layer above the back-end redistribution stack layer;

forming a single-grained prefabricated interconnected silicon core stack structure by cutting the silicon interconnection layer including the first prefabricated redistribution stack layer, the back-end redistribution stack layer and the passivation layer;

forming a first plastic packaging layer by plastic-packaging the plurality of single-grained prefabricated interconnected silicon core stack structures so as to constitute a plurality of lower packages; and

packaging the upper package above the corresponding lower package, the upper package being electrically connected to the first prefabricated redistribution stack layer.

As an optional technical solution, before the step of forming the single-grained prefabricated interconnected silicon core stack structure by cutting the silicon interconnection layer including the first prefabricated redistribution stack layer, the back-end redistribution stack layer and the passivation layer, the manufacturing method further includes the following steps:

forming a second prefabricated redistribution stack layer on the passivation layer; and forming a prefabricated chip packaging layer at a side of the second prefabricated redistribution stack layer or the first prefabricated redistribution stack layer.

As an optional technical solution, before the step of packaging the upper package above the corresponding lower package, the manufacturing method further includes the following steps:

forming the first redistribution stack layer above the lower package; and packaging the upper package above the first redistribution stack layer.

Compared with the prior art, the present invention provides a packaging structure and a manufacturing method thereof, in which a reconstituted substrate is manufactured by plastic-packaging the single-grained prefabricated interconnected silicon core stack structure. Since the prefabricated interconnected silicon core stack structure may stack the prefabricated redistribution stack layer on the silicon interconnection layer, on the one hand, the prefabricated redistribution stack layer may have smaller line width/line spacing and be thinner, thereby effectively satisfying the packaging requirements of high density and small packaging volume; and on the other hand, the prefabricated redistribution stack layer and more other redistribution stack layers may he stacked on the silicon interconnection layer for manufacture, thereby significantly improving the manufacturing yield of the packaging structure.

The present invention is described in detail below with reference to the accompanying drawings and specific embodiments, but no limitation is made to the present invention.

### BRIEF DESCRIPTION OF THE DRAWINGS

In order to describe the technical solutions in the specific embodiments of the present invention or in the prior art more clearly, the accompanying drawings required in the descriptions of the specific embodiments of the present invention or the prior art will be briefly introduced below. Apparently, the accompanying drawings in the following descriptions show only some embodiments of the present invention, and persons of ordinary skills in the art may also derive other drawings from these accompanying drawings without creative efforts.

FIG. 1 is a schematic cross-sectional view of a packaging structure according to a first embodiment of the present invention;

FIG. 2 is a schematic cross-sectional view of a packaging structure according to a second embodiment of the present invention;

FIG. 3 is a schematic cross-sectional view of a packaging structure according to a third embodiment of the present invention;

FIG. 4 is a schematic cross-sectional view of a packaging structure according to a fourth embodiment of the present invention;

FIG. 5 is a schematic cross-sectional view of a packaging structure according to a fifth embodiment of the present invention;

FIG. 6 is a schematic cross-sectional view of a packaging structure according to a sixth embodiment of the present invention;

FIG. 7 is a schematic cross-sectional view of a packaging structure according to a seventh embodiment of the present invention;

FIG. 8 is a schematic cross-sectional view of a packaging structure according to an eighth embodiment of the present invention;

FIG. 9 is a schematic cross-sectional view of a packaging structure according to a ninth embodiment of the present invention;

FIG. 10 is a schematic cross-sectional view of a packaging structure according to a tenth embodiment of the present invention;

FIG. 11 is a schematic cross-sectional view of a packaging structure according to an eleventh embodiment of the present invention;

FIG. 12 is a schematic cross-sectional view of a packaging structure according to a twelfth embodiment of the present invention;

FIG. 13 is a schematic cross-sectional view of a packaging structure according to a thirteenth embodiment of the present invention;

FIG. 14 is a schematic cross-sectional view of a packaging structure according to a fourteenth embodiment of the present invention;

FIG. 15 is a schematic cross-sectional view of a packaging structure according to a fifteenth embodiment of the present invention;

FIG. 16 is a schematic cross-sectional view of a packaging structure according to a sixteenth embodiment of the present invention;

FIG. 17 is a schematic cross-sectional view of a packaging structure according to a seventeenth embodiment of the present invention;

FIG. 18 is a schematic diagram of a manufacturing method of a packaging structure according to the present invention;

FIG. 19 is a schematic cross-sectional view of a manufacturing process of a prefabricated interconnected silicon core structure of the packaging structure in the first embodiment of the present invention;

FIG. 20 is a schematic cross-sectional view of a manufacturing process of a prefabricated chip packaging layer of the packaging structure in the first embodiment of the present invention;

FIG. 21 is a schematic cross-sectional view of a manufacturing process of a lower package of the packaging structure in the first embodiment of the present invention;

FIG. 22 is a schematic cross-sectional view of a manufacturing process of a first redistribution stack layer of the packaging structure in the first embodiment of the present invention; and

FIG. 23 and FIG. 24 are schematic cross-sectional views of manufacturing processes of an upper package and placement of a metal bump or solder ball of the packaging structure in the first embodiment of the present invention.

### DETAILED DESCRIPTION

The present invention will be described in further detail below with reference to the embodiments and the accompanying drawings, to present the objects, technical solutions and advantages of the present invention more clearly. It should be understood that the specific embodiments described herein are only used to explain the present invention rather than limit the present invention.

In the descriptions of the present invention, it is to be noted that, orientation or positional relationships indicated by terms such as “center”, “upper”, “lower”, “left”, “right”, “vertical”, “horizontal”, “inner” and “outer” are orientation or positional relationships shown based on the accompanying drawings. These terms are only used to facilitate describing the present invention and simplifying the description rather than indicate or imply that an indicated apparatus or element must have a particular orientation or be constructed and operated in the particular orientation, and thus shall not be understood as limiting to the present invention.

One of the objects of the present invention is to provide a packaging structure. The packaging structure includes a lower package and an upper package that are in electrical connection, wherein the lower package includes a prefabricated interconnected silicon core stack structure, a first plastic packaging layer surrounding the periphery of the prefabricated interconnected silicon core stack structure, and a plurality of metal bumps disposed below the prefabricated interconnected silicon core stack structure and electrically connected to the prefabricated interconnected silicon core stack structure; the prefabricated interconnected silicon core stack structure includes a silicon interconnection layer, a back-end redistribution stack layer and a passivation layer that are disposed on two surfaces of the silicon interconnection layer facing away from each other, and a first prefabricated redistribution stack layer disposed at a side of the back-end redistribution stack layer; and the silicon interconnection layer includes a silicon substrate, a plurality of through-silicon-vias formed in the silicon substrate and a plurality of first prefabricated conductive pillars embedded in the plurality of through-silicon-vias, and two opposite ends of each first prefabricated conductive pillar are exposed from a surface of the silicon substrate and a surface of the passivation layer respectively; and wherein the upper package is disposed above the first prefabricated redistribution stack layer, and is electrically connected to the first prefabricated redistribution stack layer.

In this embodiment, a reconstituted substrate is manufactured by plastic-packaging the single-grained prefabricated interconnected silicon core stack structure. Since the prefabricated interconnected silicon core stack structure may stack the prefabricated redistribution stack layer on the silicon interconnection layer, on the one hand, the prefabricated redistribution stack layer may have smaller line width/line spacing and be thinner, and thus may effectively satisfy packaging requirements of high density and small packaging volume; and on the other hand, the prefabricated redistribution stack layer stacked on the silicon interconnection layer may significantly improve the manufacturing yield of the prefabricated redistribution stack layer.

In addition, more redistribution stack layers may also be manufactured on the reconstituted substrate. More redistribution stack layers, and the prefabricated redistribution stack layer and the back-end redistribution stack layer which are in the reconstituted substrate are mutually stacked and may serve as a voltage control circuit, for example, an inductor. The inductor mainly plays a. role in filtering, oscillation, delay, trap, and the like, as well as signal screening, noise filtering, current stabilization and suppression of electromagnetic interference, and the like. Furthermore, the inductor also has characteristics of preventing the passage of alternating current and allowing the smooth passage of direct current. Preferably, the silicon substrate optionally further includes a trench-type silicon capacitor. The trench-type silicon capacitor, and the back-end redistribution stack layer and the prefabricated redistribution stack layer which are in the reconstituted substrate, and the redistribution stack layer above the reconstituted substrate are mutually stacked and may serve as a decoupling and voltage control circuit.

Further, an interconnected chip packaging layer may also be manufactured on the reconstituted substrate, and a capacitor or an inductor formed by any two or three of the conductive pillar, the interconnected chip and the plastic packaging layer which are vertically interconnected in the interconnected chip packaging layer, the interconnected redistribution stack layer on the interconnected chip, the prefabricated redistribution stack layer in the reconstituted substrate and the redistribution stack layer above the reconstituted substrate may also serve as a filter or an electrostatic protection structure.

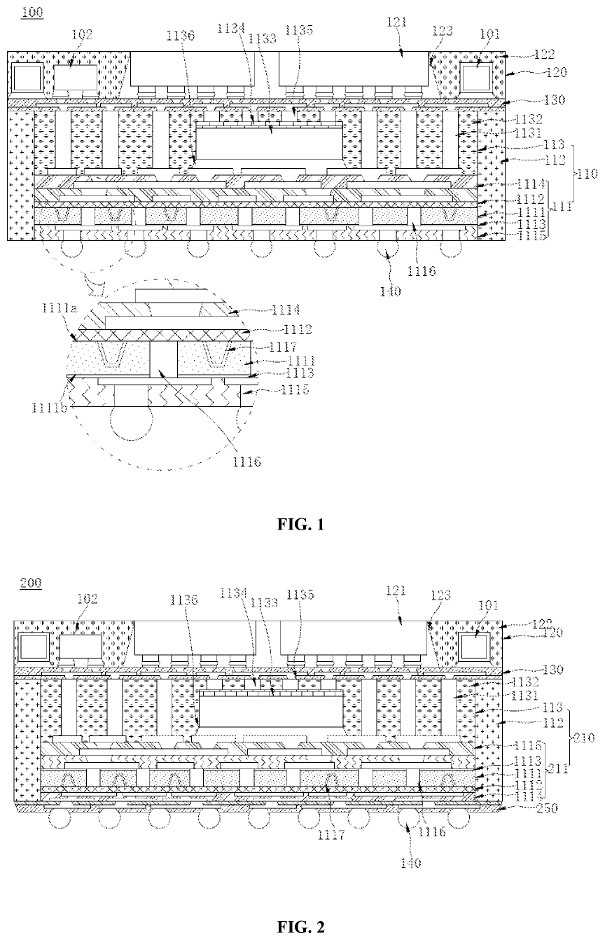

A plurality of packaging structures according to the present invention is described in detail below with reference to FIG. 1 to FIG. 17.

As shown in FIG. 1, a first embodiment of the present invention provides a packaging structure 100. The packaging structure 100 includes a lower package 110 and an upper package 120 that are in electrical connection. The lower package 110 includes a prefabricated interconnected silicon core stack structure 111 and a first plastic packaging layer 112 surrounding the periphery of the prefabricated interconnected silicon core stack structure 111. The prefabricated interconnected silicon core stack structure 111 includes a silicon interconnection layer 1111, and the silicon interconnection layer 1111 includes a first surface 1111a and a second surface 1111b facing away from each other. A back-end redistribution stack layer 1112 and a first prefabricated redistribution stack layer 1114 are stacked sequentially on the first surface 1111a and are electrically connected. A passivation layer 1113 is disposed on the second surface 1111b. The silicon interconnection layer 1111 includes a silicon substrate, several through-silicon-vias formed in the silicon substrate and several first prefabricated conductive pillars 1116 embedded in the several through-silicon-vias. Each first prefabricated conductive pillar 1116 includes a first end and a second end opposite to each other, the first end is exposed from the first surface 1111a and electrically connected to the back-end redistribution stack layer 1112, and the second end is exposed from a side of the passivation layer 1113 away from the second surface.

In this embodiment, the upper package 120 is disposed above the first prefabricated redistribution stack layer 1114, and electrically connected to the first prefabricated redistribution stack layer 1114. The upper package 120 is in indirect electrical connection with the first prefabricated redistribution stack layer 1114 through a first redistribution stack layer 130 and a prefabricated chip packaging layer 113 from top to bottom. In other embodiments of the present invention, the upper package may also be in direct electrical connection with the first prefabricated redistribution stack layer.

In a preferred embodiment, the passivation layer 1113 is, for example, a silicon nitride passivation layer, and the silicon nitride passivation layer may be formed on the second surface 1111b by vapor deposition.

In a preferred embodiment, the first prefabricated conductive pillar 1116 is, for example, a copper pillar or another metal pillar, and a passivation layer and a diffusion barrier metal layer (not shown) are provided between the first prefabricated conductive pillar 1116 and a silicon body.

With continuous reference to FIG. 1, the prefabricated interconnected silicon core stack structure 111 further includes a second prefabricated redistribution stack layer 1115 that is disposed at a side of the passivation layer 1113 away from the second surface 1111b and electrically connected to the second ends of several first prefabricated conductive pillars 1116 in the silicon interconnection layer 1111.

Preferably, the second prefabricated redistribution stack layer 1115, the passivation layer 1113, the silicon interconnection layer 1111, the back-end redistribution stack layer 1112 and the first prefabricated redistribution stack layer 1114 are stacked from bottom to top to constitute the prefabricated interconnected silicon core stack structure 111.

It is to be noted that the second prefabricated redistribution stack layer 1115, the passivation layer 1113, the silicon interconnection layer 1111, the back-end redistribution stack layer 1112 and the first prefabricated redistribution stack layer 1114 are manufactured through a wafer-level or panel-level packaging technology respectively to form the single-grained prefabricated interconnected silicon core stack structure 111 through cutting.

With continuous reference to FIG. 1, the lower package 110 further includes a prefabricated chip packaging layer 113 disposed above the first prefabricated redistribution stack layer 1114. The prefabricated chip packaging layer 113 includes several second prefabricated conductive pillars 1131, a first chip 1133 and a prefabricated plastic packaging layer 1132. Several second prefabricated conductive pillars 1131 are manufactured above the first prefabricated redistribution stack layer 1114 and electrically connected to the first prefabricated redistribution stack layer 1114. The first chip 1133 is upright-bonded above the first prefabricated redistribution stack layer 1114, the prefabricated plastic packaging layer 1132 plastic-packages the several second prefabricated conductive pillars 1131 and the first chip 1133 above the first prefabricated redistribution stack layer 1114, and the thickness of the prefabricated plastic packaging layer 1132 is 50 to 200 μm.

For example, the prefabricated chip packaging layer 113 is firstly manufactured above the wafer-level interconnected silicon core stack structure uncut into single grains through the wafer-level or panel-level packaging technology, and then cut into a single-grained reconstituted substrate, where the single-grained reconstituted substrate includes the prefabricated interconnected silicon core stack structure 111 and the prefabricated chip packaging layer 113 which are stacked, Then, the aforementioned reconstituted substrate is plastic-packaged by the first plastic packaging layer 112 to further obtain the lower package 110.

In this embodiment, the first chip 1133 is, for example, an interconnected chip upright-bonded above the first prefabricated redistribution stack layer 1114, and a surface of the first chip 1133 at a side facing toward the first redistribution stack layer 130 includes a prefabricated interconnected redistribution stack layer 1134 and a connection bump 1135 disposed above the prefabricated interconnected redistribution stack layer 1134. The connection bump 1135 is electrically connected to the first redistribution stack layer 130 and the first chip 1133. The minimum line width/line spacing of the prefabricated interconnected redistribution stack layer 1134 is less than 2 μm, and the prefabricated interconnected redistribution stack layer 1134 includes at least one capacitor.

As shown in FIG. 1, the packaging structure 100 further includes a first redistribution stack layer 130 that is disposed between the upper package 120 and the lower package 110 and electrically connected to the upper package 120 and the lower package 110. The first redistribution stack layer 130 is disposed above the prefabricated chip packaging layer 113, and electrically connected to several second prefabricated conductive pillars 1131.

In a preferred embodiment, a chip mounting layer 1136 is filled between the first chip 1133 and the first prefabricated redistribution stack layer 1114 to enable the fixed connection between the first chip 1133 and the first prefabricated redistribution stack layer 1114 to be more stable and/or to play a role in electrode connection and enhancement of heat dissipation, and to further prevent the first chip 1133 from being affected by harmful operation environments such as moisture and vibration.

In a preferred embodiment, the minimum line width/line spacing of the back-end redistribution stack layer 1112 is less than 2 μm, the minimum line width/line spacing of the first prefabricated redistribution stack layer 1114 is less than 10 μm, and the minimum line width/line spacing of the first redistribution stack layer 130 is less than 5 μm.

A capacitor or an inductor formed by any two or three of the first redistribution stack layer 130 (the minimum line width/line spacing is less than 5 μm), the prefabricated interconnected redistribution stack layer 1134 (the minimum line width/line spacing is less than 2 μm) and the first prefabricated redistribution stack layer 1114 (the minimum line width/line spacing is less than 10 μm) which are stacked from top to bottom may serve as a filter, an electrostatic protection structure or a voltage control structure.

In addition, the silicon interconnection layer 1111 further includes a trench-type silicon capacitor 1117 disposed in the silicon substrate. A decoupling and voltage control circuit is formed by any two or three or four of the first redistribution stack layer 130 (the minimum line width/line; spacing is less than 5 μm), the first prefabricated redistribution stack layer 1114 (the minimum line width/line spacing is less than 10 μm), the back-end redistribution stack layer 1112 (the minimum line width/line spacing is less than 2 μm) and the trench-type silicon capacitor 1117 which are stacked from top to bottom,

As shown in FIG. 1, the upper package 120 includes a chip 121 and/or a device package 121. For example, the chip 121 and/or the device package 121 is flip-bonded above the first redistribution stack layer 130, and electrically connected to the first redistribution stack layer 130. A second plastic packaging layer 122 plastic-packages the chip 121 and/or the device package 121 above the first redistribution stack layer 130. The second plastic packaging layer 122 is optional, and the thickness thereof is 150 to 780 μm.

Preferably, an underfill material layer 123 is filled between the chip 121 and/or the device package 121 and the first redistribution stack layer 130. The underfill material layer 123 enables the chip 121 and/or the device package 121 to be fixedly connected to the first redistribution stack layer 130 more stably, and may also prevent the chip 121 and/or the device package 121 from being affected by harmful operation environments such as moisture and vibration.

A metal block or frame 101 is embedded in the second plastic packaging layer 122 of the upper package 120, and may be a metal or silicon block coated with a metal surface, or a silicon core, which is connected to the first redistribution stack layer 130 by metal bonding or adhesive bonding, disposed above the first redistribution stack layer 130, and preferably located at an edge and/or corner of the first redistribution stack layer 130, for improving warpage and the heat dissipation of the packaging structure 100 and shielding the electromagnetic interference.

In addition, a functional device 102 may also be embedded in the second plastic packaging layer 122, and electrically connected to the first redistribution stack layer 130. The functional device 102 may be a functional device such as a capacitor or an inductor.

As shown in FIG. 1, the packaging structure 100 further includes a metal bump or solder ball 140 that is disposed below a second prefabricated redistribution stack layer 1115 and electrically connected to a conductive layer in the second prefabricated redistribution stack layer 1115, for electrical signal transmission of the packaging structure 100.

In this embodiment, for example, each structure of the upper package 12.0 is manufactured above the reconstituted substrate which is formed after the prefabricated interconnected silicon core stack structure 111 and the prefabricated chip packaging layer 113 are plastic-packaged in advance by wafer-level packaging or panel-level packaging, but this is not limiting. In the packaging structure according to another embodiment of the present invention, the upper package may also be a pre-packaged separate unit. When the prefabricated interconnected silicon core stack structure cut into single grains and the prefabricated chip packaging layer are plastic-packaged to form the reconstituted substrate on which the first redistribution stack layer is manufactured, two separate units are bonded with each other to enable electrical connection. Thus, such stack connection of separate units facilitates improving the yield of the overall packaging structure.

As shown in FIG. 2, a second embodiment of the present invention further provides a packaging structure 200. The packaging structure 200 is different from the packaging structure 100 in that, 1) in a prefabricated interconnected silicon core stack structure 211 of the packaging structure 200, the back-end redistribution stack layer 1112 is disposed on the second surface 1111b (as shown in FIG. 1) of the silicon interconnection layer 1111, and the passivation layer 1113 is disposed on the first surface 1111a (as shown in FIG. 1) of the silicon interconnection layer 1111; 2) the trench-type capacitor 1117 is electrically connected to the back-end redistribution stack layer 1112 located at a side of the second surface 1111b (as shown in FIG. 1); 3) the prefabricated chip packaging layer 113 is disposed above the second prefabricated redistribution stack layer 1115, and electrically connected to the second prefabricated redistribution stack layer 1115; 4) a back-surface redistribution stack layer 250 is further disposed below the lower package 110, and electrically connected to the second prefabricated redistribution stack layer 1115; and 5) the metal bump or solder ball 140 is disposed below the back-surface redistribution stack layer 250, and electrically connected to a conductive layer in the back-surface redistribution stack layer 250.

It is to be noted that the back-surface redistribution stack layer 250 is not a prefabricated. structure. The prefabricated interconnected silicon core stack structure 111 and the prefabricated chip packaging layer 113 which are stacked are cut into single grains, and then plastic-packaged by the first plastic packaging layer 112 to constitute the reconstituted substrate; and then, the reconstituted substrate is packaged through the wafer-level or panel-level packaging technology to form the back-surface redistribution stack layer 250 on a back surface of the reconstituted substrate. Preferably, the minimum line width/line spacing of the back-surface redistribution stack layer 250 is less than or equal to 5 μm.

In addition, it can be seen from FIG. 1 and FIG. 2. that the lower packages 110 and 210 both include the prefabricated chip packaging layer 113. Based on a stack position of the first prefabricated redistribution stack layer 1114 and the second prefabricated redistribution stack layer 1115 in the prefabricated interconnected silicon core stack structures 111 and 211, the prefabricated chip packaging layer 113 may be disposed at a side of the first prefabricated redistribution stack layer 1114, or disposed at a side of the second prefabricated redistribution stack layer 1115.

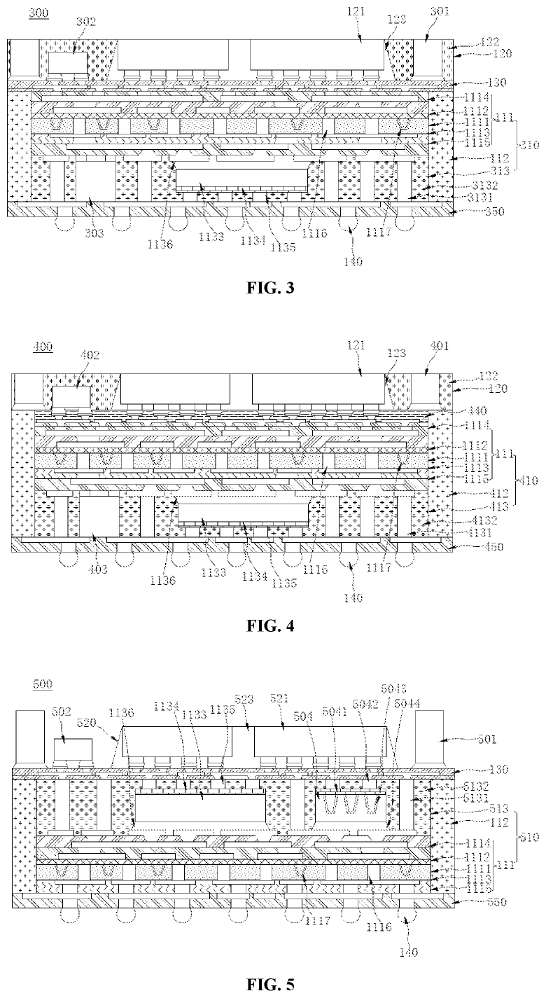

In this embodiment, the prefabricated chip packaging layer 113 is located above the prefabricated interconnected silicon core stack structure 111 or 211, that is, the prefabricated chip packaging layer 113 is sandwiched between the upper package 120 and the prefabricated interconnected silicon core stack structure 111 or 211, but, this is not limiting. In packaging structures 300 and 400 in a third embodiment and a fourth embodiment shown in FIG. 3 and FIG. 4 of the present invention, similar prefabricated chip packaging layers 313 and 413 may be further disposed below the prefabricated interconnected silicon core stack structures 111, that is, similar prefabricated chip packaging layers are located at the bottom of the entire packaging structures.

In other words, in the packaging structure of the present invention, the prefabricated chip packaging layer may be disposed at a side of the first prefabricated redistribution stack layer, or disposed at a side of the second prefabricated redistribution stack layer. The prefabricated chip packaging layer is sandwiched between the upper package and the first prefabricated redistribution stack layer, or alternatively sandwiched between the upper package and the second prefabricated redistribution stack layer. Still alternatively, the prefabricated chip packaging layer may be sandwiched between the prefabricated interconnected silicon core stack structure and the back-surface redistribution stack layer and located at the bottom of the packaging structure.

In addition, the same reference numerals in FIG. 2 and FIG. 1 indicate that same elements have similar functions, which is not further described in detail.

As shown in FIG. 3, the third embodiment of the present intention further provides a. packaging structure 300. The packaging structure 300 is different from the packaging structure 100 in that, 1) in the packaging structure 300, a lower package 310 includes the prefabricated interconnected silicon core stack structure 111 and a prefabricated chip packaging layer 313 stacked below the prefabricated interconnected silicon core stack structure 111, and the prefabricated chip packaging layer 313 is electrically connected to the second prefabricated redistribution stack layer 1115 in the prefabricated interconnected silicon core stack structure 111 through second prefabricated conductive pillars 3131; 2) a back-surface redistribution stack layer 350 is further disposed below the lower package 310, and electrically connected to the second prefabricated conductive pillars 3131 in the prefabricated chip packaging layer 313; 3) the metal bump or solder ball 140 is disposed below the back-surface redistribution stack layer 350. and electrically connected to a conductive layer in the back-surface redistribution stack layer 350; 4) a third functional block 303 is embedded in a prefabricated plastic packaging layer 3132 of the prefabricated chip packaging layer 313, and electrically connected to the second prefabricated redistribution stack layer 1115 and the back-surface redistribution stack layer 350; preferably, the third functional block 303 includes but is not limited to a magnetic block, an inductor, an antenna, a silicon capacitor chip, an embedded composite block with a high-k thin-film capacitor, a ceramic (PZT) sensor, a capacitor package, and the like; and 5) an auxiliary structure 301 and a functional device 302 are also embedded in the upper package 120, the auxiliary structure 301 includes a metal block, a reinforcing block, a heat dissipation block, and the like, is disposed above the first redistribution stack layer 130, and preferably located at the edge and/or corner of the first redistribution stack layer 130, for improving the warpage and the heat dissipation of the packaging structure 300 and shielding the electromagnetic interference; and the functional device 302 is electrically connected to the first redistribution stack layer 130, and may be a functional device such as a capacitor or an inductor.

In this embodiment, the prefabricated chip packaging layer 313 is located at the bottom of the lower package 310, sandwiched between the second prefabricated redistribution stack layer 1115 and the back-surface redistribution stack layer 350, and located at the bottom of the packaging structure 300. The prefabricated plastic packaging layer 3132 in the prefabricated chip packaging layer 313 plastic-packages the first chip 1133 and several second prefabricated conductive pillars 3131 at a side of the second prefabricated redistribution stack layer 1115. The chip mounting layer 1136 is filled between the first chip 1133 and the second prefabricated redistribution stack layer 1115, and the first chip 1133 includes the prefabricated interconnected redistribution stack layer 1134 and the connection bump 1135 at a side facing toward the back-surface redistribution stack layer 350, where the connection bump 1135 is electrically connected to the prefabricated interconnected redistribution stack layer 1134 and the back-surface redistribution stack layer 350.

In addition, the same reference numerals in FIG. 3 and FIG. 1 indicate that same elements have similar functions, which is not further described in detail.

As shown in FIG. 4, the fourth embodiment of the present invention further provides a packaging structure 400. The packaging structure 400 is different from the packaging structure 100 in that, 1) in the packaging structure 400, the upper package 120 is in direct electrical connection with the first prefabricated redistribution stack layer 1114 in the prefabricated interconnected silicon core stack structure 111 in a lower package 410; 2) the lower package 410 further includes a solder mask layer 440 that is disposed above the first prefabricated redistribution stack layer 1114 and plastic-packaged by a first plastic packaging layer 412; 3) the lower package 410 includes the prefabricated interconnected silicon core stack structure 111 and a prefabricated chip packaging layer 413 stacked below the prefabricated interconnected silicon core stack structure 111, and the prefabricated chip packaging layer 413 is electrically connected to the second prefabricated redistribution stack layer 1115 in the prefabricated interconnected silicon core stack structure 111 through second prefabricated conductive pillars 4131; 4) a back-surface redistribution stack layer 450 is further disposed below the lower package 410, and electrically connected to the second prefabricated conductive pillars 4131 in the prefabricated chip packaging layer 413; and 5) the metal bump or solder ball 140 is disposed below the back-surface redistribution stack layer 450, and electrically connected to a conductive layer in the back-surface redistribution stack layer 450.

In this embodiment, the prefabricated chip packaging layer 413 is located at the bottom of the lower package 410, is sandwiched between the second prefabricated redistribution stack layer 1115 and the back-surface redistribution stack layer 450, and is located at the bottom of the packaging structure 400. A prefabricated plastic packaging layer 4132 in the prefabricated chip packaging layer 413 plastic-packages the first chip 1133 and several second prefabricated conductive pillars 4131 at a side of the second prefabricated redistribution stack layer 1115. The chip mounting layer 1136 is filled between the first chip 1133 and the second prefabricated redistribution stack layer 1115, and the first chip 1133 includes the prefabricated interconnected redistribution stack layer 1134 and the connection bump 1135 at a side facing toward the back-surface redistribution stack layer 450, where the connection bump 1135 is electrically connected to the prefabricated interconnected redistribution stack layer 1134 and the back-surface redistribution stack layer 450.

in addition, a third functional block 403 is embedded in the prefabricated plastic packaging layer 4132 of the prefabricated chip packaging layer 413, and electrically connected to the second prefabricated redistribution stack layer 1115 and the back-surface redistribution stack layer 450. Preferably, the third functional block 403 includes but is not limited to a magnetic block, an inductor, an antenna, a silicon capacitor chip, an embedded composite block with a high-k thin-film capacitor, a ceramic (PZT) sensor, a capacitor package, and the like.

An auxiliary structure 401 and a functional device 402 are also embedded in the upper package 120. The auxiliary structure 401 includes a metal block, a reinforcing block, a heat dissipation block, and the like, and is disposed above the lower package 410, and preferably located at an edge and/or corner of the lower package 410, for improving the warpage and the heat dissipation of the packaging structure 400 and shielding the electromagnetic interference. The functional device 402 is electrically connected to the first prefabricated redistribution stack layer 1114, and may be a functional device such as a capacitor or an inductor.

In addition, the same reference numerals in FIG. 4 and FIG. 1 indicate that same elements have similar functions, which is not further described in detail.

As shown in FIG. 5, a fifth embodiment of the present invention further provides a packaging structure 500. The packaging structure 500 is different from the packaging structure 100 in that, 1) in the packaging structure 500, a prefabricated chip packaging layer 513 of a lower package 510 further includes a second chip 504 embedded in a prefabricated plastic packaging layer 5132, and the second chip 504 and the first chip 1133 are horizontally disposed side by side, and disposed above the first prefabricated redistribution stack layer 1114 respectively, wherein the second chip 504 includes but is not limited to a silicon capacitor chip, an interconnected redistribution stack layer 5041 and a connection bump 5042 are disposed on a surface of the silicon capacitor chip at a side facing toward the first redistribution stack layer 130, and the connection bump 5042 is electrically connected to the first redistribution stack layer 130 and the interconnected redistribution stack layer 5041; furthermore, a trench-type capacitor 5043 is disposed in the silicon capacitor chip, and electrically connected to the interconnected redistribution stack layer 5041; 2) a chip mounting layer 5044 is filled between the second chip 504 and the first prefabricated redistribution stack layer 1114 to enable the second chip 504 to be stably connected above the first prefabricated redistribution stack layer 1114, and to further prevent the second chip 504 from being affected by harmful operation environments such as moisture and vibration; 3) the upper package includes a chip 521 and/or a device package 521 flip-bonded above the first redistribution stack layer 130, and an underfill material layer 523 is filled between the chip 521 and/or the device package 521 and the first redistribution stack layer 130; and 4) an auxiliary structure 501 and a functional device 502 are disposed at the edge and/or corner of the first redistribution stack layer 130; the auxiliary structure 501 includes a metal block_{;} a reinforcing block, a heat dissipation block, and the like, for improving the warpage and the heat dissipation of the packaging structure 500 and shielding the electromagnetic interference; and the functional device 502 is electrically connected to the first redistribution stack layer 130, and may be a functional device such as a capacitor or an inductor.

In this embodiment, the prefabricated chip packaging layer 513 is stacked above the prefabricated interconnected silicon core stack structure 111, and sandwiched between the first redistribution stack layer 130 and the first prefabricated redistribution stack layer 1114. The prefabricated chip packaging layer 513 is electrically connected to the first redistribution stack layer 130 and the first prefabricated redistribution stack layer 1114 through second prefabricated conductive pillars 5131.

In addition, the same reference numerals in FIG. 5 and FIG. 1 indicate that same elements have similar functions, which is not further described in detail.

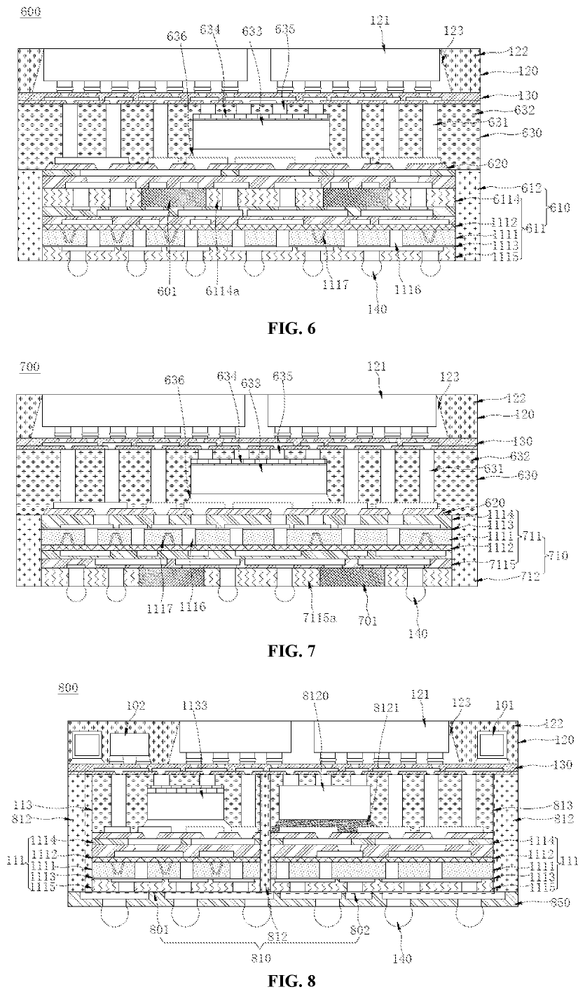

As shown in FIG. 6, a sixth embodiment of the present invention further provides a packaging structure 600, The packaging structure 600 is different from the packaging structure 100 in that, 1) in the packaging structure 600, a lower package 610 includes a prefabricated interconnected silicon core stack structure 611 and a first plastic packaging layer 612 surrounding the periphery of the interconnected silicon core stack structure 611; the prefabricated interconnected silicon core stack structure 611 is constituted by the second prefabricated redistribution stack layer 1115, the passivation layer 1113, the silicon interconnection layer 1111, the back-end redistribution stack layer 1112 and a first prefabricated redistribution stack layer 6114 which are stacked from bottom to top; 2) the first prefabricated redistribution stack layer 6114 includes a first base material layer 6114a, at least one first functional block 601 is embedded in the first base material layer 6114a, and the first functional block 601 includes but is not limited to a magnetic block, an inductor, an antenna, a silicon capacitor chip, an embedded composite block with a high-k thin film capacitor, a ceramic (PZT) sensor, a capacitor package, and the like; preferably, for example, the first functional block 601 is stacked below the corresponding chip 121 and/or the device package 121 in the upper package 120 along a thickness direction or a stack direction of the packaging structure 600; 3) a second redistribution stack layer 620 and an interconnected chip packaging layer 630 are disposed between the upper package 120 and the lower package 610; the second redistribution stack layer 620 is formed above the lower package 610, and electrically connected to the first prefabricated redistribution stack layer 6114; the interconnected chip packaging layer 630 is disposed above the second redistribution stack layer 620, and electrically connected to the first redistribution stack layer 130 and the second redistribution stack layer 620; and 4) the interconnected chip packaging layer 630 includes several conductive pillars 631, a third plastic packaging layer 632 and an interconnected chip 633; the several conductive pillars 631 are formed above the second redistribution stack layer 620, and an end of each conductive pillar 631 is electrically connected to a pad exposed from a dielectric layer in the second redistribution stack layer 620; the interconnected chip 633 is upright-mounted above the second redistribution stack layer 620, an interconnected redistribution stack layer 634 and a connection bump 635 are disposed on a surface of the interconnected chip 633 at a side facing toward the first redistribution stack layer 130, and the connection bump 635 is electrically connected to the first redistribution stack layer 130 and the interconnected redistribution stack layer 634; and the third plastic packaging layer 632 plastic-packages several conductive pillars 631 and the interconnected chip 633 above the second redistribution stack layer 620.

The minimum line width/line spacing of the interconnected redistribution stack layer 634 is less than 2 μm, and the interconnected redistribution stack layer 634 further includes at least one capacitor; and the minimum line width/line spacing of the second redistribution stack layer 620 is less than 10 μm.

In this embodiment, the first prefabricated redistribution stack layer 6114 (the minimum line width/line spacing is less than 10 μm), the second redistribution stack layer 620 (the minimum line width/line spacing is less than 10 μm), the interconnected redistribution stack layer 634 (the minimum line width/line spacing is less than 10 μm) and the second redistribution stack layer 620 (the minimum line width/line spacing is less than 5 μm) are stacked from bottom to top, where a capacitor or an inductor formed by any two or three of the above may serve as a filter, a electrostatic protection structure or a voltage control structure.

In addition, the same reference numerals in FIG. 6 and FIG. 1 indicate that same elements have similar functions, which is not further described in detail.

As shown in FIG. 7, a seventh embodiment of the present invention further provides a packaging structure 700. The packaging structure 700 is different from the packaging structure 600 in that, in the packaging structure 700, a lower package 710 includes a prefabricated interconnected silicon core stack structure 711 and a first plastic packaging layer 712 surrounding the periphery of the prefabricated interconnected silicon core stack structure 711, wherein the prefabricated interconnected silicon core stack structure 711 is formed by a second prefabricated redistribution stack layer 7115, the passivation layer 1113, the silicon interconnection layer 1111, the back-end redistribution stack layer 1112 and the first prefabricated redistribution stack layer 1114 which are stacked from bottom to top.

The second prefabricated redistribution stack layer 7115 includes a second base material layer 7115a, at least one second functional block 701 is embedded in the second base material layer 7115a, and the second functional block 701 includes but is not limited to a magnetic block, an inductor, an antenna, a silicon capacitor chip, an embedded composite block with a high-k thin film capacitor, a ceramic (PTT) sensor, a capacitor package, and the like. Preferably, for example, the second functional block 701 is stacked below the corresponding chip 121 and/or the device package 121 in the upper package 120 along a thickness direction or a stack direction of the packaging structure 700.

In the packaging structures 600 and 700 shown in FIG. 6 and FIG, 7, at least one first functional block 601 and at least one second functional block 701 are embedded in the first prefabricated redistribution stack layer 6114 and the second prefabricated redistribution stack layer 7115 above or below the silicon interconnection layer 1111 respectively. It is to be noted that the functional blocks may be embedded in both the first prefabricated redistribution stack layer and the second prefabricated redistribution stack layer according to actual requirements in other embodiments of the present invention.

In other words, in the lower package, the corresponding first functional block and/or the corresponding second functional block may be embedded in the first prefabricated redistribution stack layer and/or the second prefabricated redistribution stack layer on the first surface and the second surface of the silicon interconnection layer facing away from each other. Preferably, the first functional block and/or the second functional block are stacked below the corresponding chip and/or device package in the upper package in the thickness direction of the packaging structure.

in addition, the same reference numerals in FIG. 7 and FIG. 6 indicate that same elements have similar functions, which is not further described in detail.

As shown in FIG. 8, an eighth embodiment of the present invention further provides a packaging structure 800. The packaging structure 800 is different from the packaging structure 100 in the following aspects.

1) In the packaging structure 800, two prefabricated interconnected silicon core stack structures 111 are plastic-packaged in a first plastic packaging layer 812 of a lower package 810; and two prefabricated interconnected silicon core stack structures 111 are similar in film structure but difference in size, where corresponding prefabricated chip packaging layers are disposed above two prefabricated interconnected silicon core stack structures 111 respectively. For ease of description, the corresponding prefabricated chip packaging layers are defined as the first prefabricated chip packaging layer 113 and a second prefabricated chip packaging layer 813, where the first prefabricated chip packaging layer 113 is disposed above one of two prefabricated interconnected silicon core stack structures 111 and constitutes a first prefabricated stacking unit 801, the second prefabricated chip packaging layer 813 is disposed above the other of two prefabricated interconnected silicon core stack structures 111 and constitutes a second prefabricated stacking unit 802, the first prefabricated stacking unit 801 and the second prefabricated stacking unit 802 are plastic-packaged by the first plastic packaging layer 812 to form the lower package 810, and the first prefabricated stacking unit 801 and the second prefabricated stacking unit 802 are electrically connected to the first redistribution stack layer 130 respectively.

2) The second prefabricated chip packaging layer 813 includes a third chip 8120 electrically connected to the first prefabricated redistribution stack layer 1114 in the first prefabricated interconnected silicon core stack structure 111 through a conductive material layer 8121, and the third chip 8120 and the first chip 1133 have different functions.

3) A back-surface redistribution stack layer 850 is disposed below the lower package 810, and electrically connected to the second prefabricated redistribution stack layer 1115 in the first prefabricated interconnected silicon core stack structure 111 and the second prefabricated redistribution stack layer 1115 in the second prefabricated interconnected silicon core stack structure 111 respectively, where the metal bump or solder ball 140 is disposed on a back surface of the back-surface redistribution stack layer 850 and electrically connected to the back-surface redistribution stack layer 850, and the first prefabricated stacking unit 801 and the second prefabricated stacking unit 802 are electrically connected to the back-surface redistribution stack layer 850 respectively.

In this embodiment, in the packaging structure 800, two prefabricated stacking units, i.e., the first prefabricated stacking unit 801 and the second prefabricated stacking unit 802 with different functions are plastic-packaged by the first plastic packaging layer 812 to form the lower package 810. The first prefabricated stacking unit 801 and the second prefabricated stacking unit 802 are manufactured in the wafer-level or panel-level packaging technology respectively, and cut in advance into single grains to finish a performance test, and then plastic-packaged to constitute the reconstituted substrate. Therefore, on the one hand, the reconstituted substrate may be provided with a plurality of functions; and on the other hand, the yield of the chip embedded in the reconstituted substrate may be improved. That is, the reconstituted substrate is reconstituted by plastic-packaging a prefabricated block in which the chip is embedded, thereby facilitating the functional diversification of the packaging structure and the yield of the embedded chip.

It is to be noted that, the first plastic packaging layer may also plastic-package more than two prefabricated stacking units with similar functions and same or different sizes to constitute the lower package in other embodiments of the present invention. Further, in the prefabricated stacking unit, the prefabricated chip packaging layer may also be stacked below the prefabricated interconnected silicon core stack structure, and located at the bottom of the packaging structure or the lower package.

In addition, the same reference numerals in FIG. 8 and FIG. 1 indicate that same elements have similar functions, which is not further described in detail.

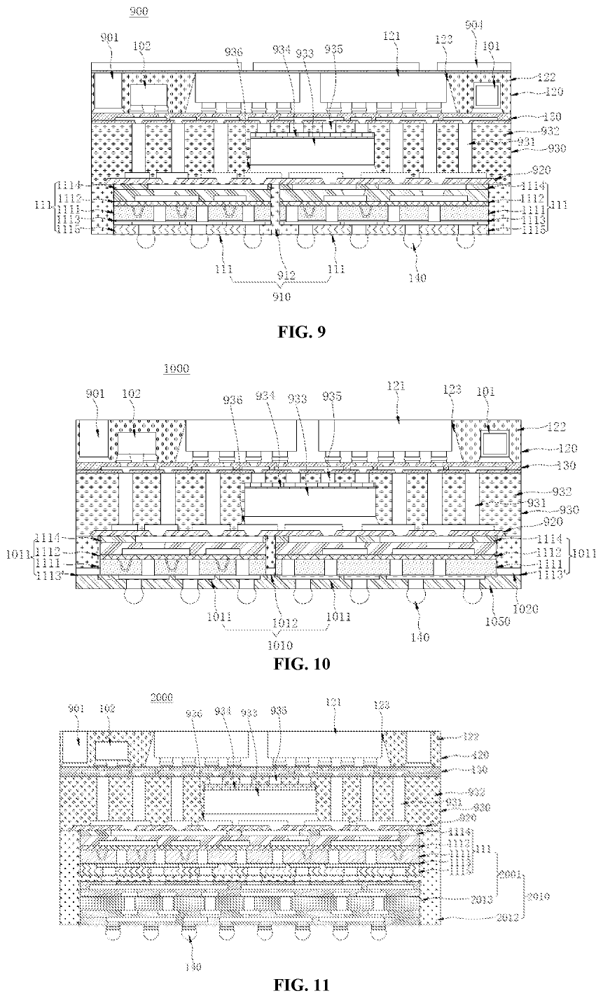

As shown in FIG. 9, a ninth embodiment of the present invention further provides a packaging structure 900. The packaging structure 900 is different from the packaging structure 100 in the following aspects.

1) In the packaging structure 900, two prefabricated interconnected silicon core stack structures 111 are plastic-packaged in a first plastic packaging layer 912 to form a lower package 910, where film structures and sizes of two prefabricated interconnected silicon core stack structures 111 may be same or different.

2) A second redistribution stack layer 920 is disposed above the lower package 910, the minimum line width/line spacing of the second redistribution stack layer 920 is less than 10 μm, and an interconnected chip packaging layer 930 is disposed above the second redistribution stack layer 920; the first redistribution stack layer 130 is disposed above the interconnected chip packaging layer 930, and the minimum line width/line spacing of the interconnected chip packaging layer 930 is less than 5 μm; and the upper package 120 is disposed above the first redistribution stack layer 130.

3) The interconnected chip packaging layer 930 includes several conductive pillars 931, a third plastic packaging layer 932 and an interconnected chip 933; several conductive pillars 931 are formed above the second redistribution stack layer 920, and an end of each conductive pillar 931 is electrically connected to a pad exposed from a dielectric layer in the second redistribution stack layer 920; the interconnected chip 933 is upright-mounted above the second redistribution stack layer 920, an interconnected redistribution stack layer 934 and a connection bump 935 are disposed on a surface of the interconnected chip 933 at a side facing toward the first redistribution stack layer 130, and the connection bump 935 is electrically connected to the first redistribution stack layer 130 and the interconnected redistribution stack layer 934; and the third plastic packaging layer 932 plastic-packages several conductive pillars 931 and the interconnected chip 933 above the second redistribution stack layer 920.

4) Two prefabricated interconnected silicon core stack structures 111 are electrically connected to the second redistribution stack layer 920 respectively.

5) Another auxiliary structure 901 is embedded in the second plastic packaging layer 122 of the upper package 120, and includes but is not limited to a metal block, a heat dissipation block and a reinforcing block; and the auxiliary structure 901 is disposed at the edge and/or corner of the first redistribution stack layer 130, for improving the warpage and the heat dissipation of the packaging structure 900 and shielding the electromagnetic interference.

6) A composite multi-layer metal heat sink 904 is further disposed on the surface of the upper package 120 at a side away from the first redistribution stack layer 130, and includes a patterned metal layer and/or a patterned dielectric layer, where the patterned metal layer and/or the patterned dielectric layer are used to avoid the warpage of the packaging structure 900 and balance the stress.

In addition, the same reference numerals in FIG. 9 and FIG. 8 indicate that same elements have similar functions, which is not further described in detail.

As shown in FIG. 10, a tenth embodiment of the present invention further provides a packaging structure 1000. The packaging structure 1000 is different from the packaging structure 900 in the following aspects.

1) A prefabricated interconnected silicon core stack structure 1011 is constituted by a passivation layer 1113′, the silicon interconnection layer 1111, the back-end redistribution stack layer 1112 and the first prefabricated redistribution stack layer 1114 which are stacked from bottom to top, where an edge of the passivation layer 1113′ protrudes from an edge of the silicon interconnection layer 1111 and is partially stacked above a surface at a side of a first plastic packaging layer 1012. Preferably, a planarization layer 1020 is disposed between the edge of the passivation layer 1113′ and the first plastic packaging layer 1012 to avoid the warpage of the edge of a lower package 1010 at high temperatures.

2) The second surface 1111b (as shown in FIG. 1) of the silicon interconnection layer 1111 on which the passivation layer 1113 is disposed protrudes from a back side of the first plastic packaging layer 1012.

3) Two prefabricated interconnected silicon core stack structures 1011 are plastic-packaged by the first plastic packaging layer 1012 to form the lower package 1010, where film structures and sizes of two prefabricated interconnected silicon core stack structures 1011 may be same or different.

4) A back-surface redistribution stack layer 1050 disposed below the lower package 1010 is further included, and the metal bump or solder ball 140 is disposed at a back side of the back-surface redistribution stack layer 1050 and electrically connected to a conductive layer in the back-surface redistribution stack layer 1050, where an edge of the back-surface redistribution stack layer 1050 protrudes from an edge of the prefabricated interconnected silicon core stack structure 1011 and covers the edge of the passivation layer 1113′.

5) Two prefabricated interconnected silicon core stack structures 1011 are electrically connected to the second redistribution stack layer 920 and the back-surface redistribution stack layer 1050 respectively.

In addition, the same reference numerals in FIG. 10 and FIG. 9 indicate that same elements have similar functions, which is not further described in detail.

As shown in FIG. 11, an eleventh embodiment of the present invention further provides a packaging structure 2000. The packaging structure 2000 is different from the packaging structure 900 in the following aspects.

1) In the packaging structure 2000, a lower package 2010 includes one prefabricated interconnected silicon core stack structure 111 and a first prefabricated substrate 2013; the first prefabricated substrate 2013 and the one prefabricated interconnected silicon core stack structure 111 are stacked vertically to constitute a first prefabricated unit 2001, where the first prefabricated unit 2001 is plastic-packaged by a first plastic packaging layer 2012 to form the lower package 2010, and the first prefabricated substrate 2013 is, for example, a laminated substrate including a base material layer, and a conductive layer and a dielectric layer alternately stacked on the base material layer.

2) The prefabricated interconnected silicon core stack structure 111 is electrically connected to the first prefabricated substrate 2013 and the second redistribution stack layer 920, wherein the manner in which the prefabricated interconnected silicon core stack structure 111 is electrically connected to the first prefabricated substrate 2013 includes but is not limited to tin-gold bonding or copper-copper diffusion bonding.

3) The metal bump or solder ball 140 is formed on a back surface of the first prefabricated substrate 2013.

In other embodiments of the present invention, an underfill material layer may also be filled between the prefabricated interconnected silicon core stack structure and the first prefabricated substrate to fix the prefabricated interconnected silicon core stack structure on the first prefabricated substrate so as to constitute the first prefabricated unit with better stability, and then the first prefabricated unit is plastic-packaged by the first plastic packaging layer to constitute the reconstituted substrate.

It is to be noted that the prefabricated interconnected silicon core stack structure may also be stacked below the first prefabricated substrate to constitute the first prefabricated unit according to actual requirements in other embodiments of the present invention. In other words, the prefabricated interconnected silicon core stack structure may he disposed on at least one side of a third surface and a fourth surface of the first prefabricated substrate facing away from each other to constitute the first prefabricated unit with the first prefabricated substrate according to actual requirements, and the first prefabricated unit is plastic-packaged by the first plastic packaging layer to form the reconstituted substrate or the lower package.

In addition, the same reference numerals in FIG. 11 and FIG. 9 indicate that same elements have similar functions, which is not further described in detail.

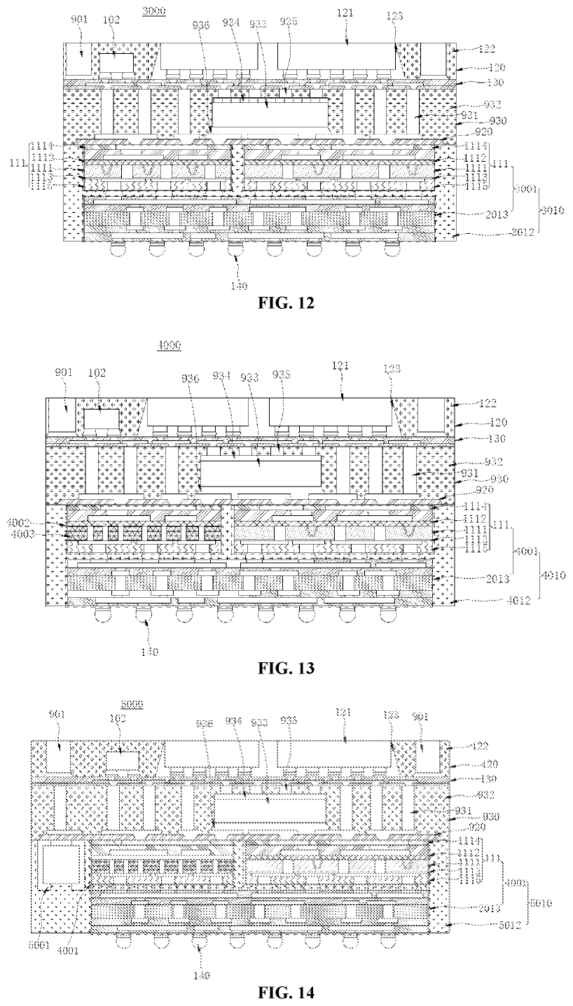

As shown in FIG. 12, a twelfth embodiment of the present invention further provides a packaging structure 3000. The packaging structure 3000 is different from the packaging structure 2000 in the following aspect.

In the packaging structure 3000, two horizontally-arranged. prefabricated interconnected silicon core stack structures 111 are stacked above the first prefabricated substrate 2013 to constitute a first prefabricated unit 3001 with the first prefabricated substrate 2013, and then, the first prefabricated unit 3001 is plastic-packaged by the first plastic packaging layer 3012 to form a lower package 3010.

Two horizontally-arranged prefabricated interconnected silicon core stack structures 111 are electrically connected to the first prefabricated substrate 2013 and the second redistribution stack layer 920.

In addition, the same reference numerals in FIG. 12 and FIG, 11 indicate that same elements have similar functions, which is not further described in detail.

As shown in FIG. 13, a thirteenth embodiment of the present invention further provides a packaging structure 4000. The packaging structure 4000 is different from the packaging structure 2000 in the following aspect.

In the packaging structure 4000, one prefabricated interconnected silicon core stack structure 111 and one second prefabricated substrate 4002 are stacked above the first prefabricated substrate 2013, and the prefabricated interconnected silicon core stack structure 111 and the second prefabricated substrate 4002 are arranged horizontally on a surface at a side of the first prefabricated substrate 2013, where a base material layer 4003 of the second prefabricated substrate 4002 is different from that of the first prefabricated substrate 2013.

The prefabricated interconnected silicon core stack structure 111 and the second prefabricated substrate 4002 are bonded above the first prefabricated substrate 2013 and electrically connected to the first prefabricated substrate 2013 respectively. Moreover, the prefabricated interconnected silicon core stack structure 111 and the second prefabricated substrate 4002 are electrically connected to the second redistribution stack layer 920 respectively.

The second prefabricated substrate 4002 also is, for example, a laminated substrate, and the material of the base material layer 4003 may be selected from glass, ceramic, and the like.

In addition, a functional material may also be filled in the base material layer of the first prefabricated substrate 2013, and the functional material includes a heat-resistant filler, a magnetic filler, and the like.

In this embodiment, the first prefabricated substrate 2013, the second prefabricated substrate 4002 and the prefabricated interconnected silicon core stack structure 111 constitute a first prefabricated unit 4001, and the first prefabricated unit 4001 is plastic-packaged by the first plastic packaging layer 4012 to form a lower package 4010.

In addition, the same reference numerals in FIG. 13 and FIG. 11 indicate that same elements have similar functions, which is not further described in detail.

As shown in FIG. 14, a fourteenth embodiment of the present invention further provides a packaging structure 5000. The packaging structure 5000 is different from the packaging structure 4000 in the following aspect.

In the packaging structure 5000, the first prefabricated unit 4001 is plastic-packaged in a first plastic packaging layer 5012 to form a lower package 5010, where a functional block 5001 is embedded in the first plastic packaging layer 5012, and the functional block 5001 is a large inductor or another element electrically connected to the second prefabricated redistribution stack layer 1115.

In addition, the same reference numerals in FIG. 14 and FIG. 13 indicate that same elements have similar functions, which is not further described in detail.

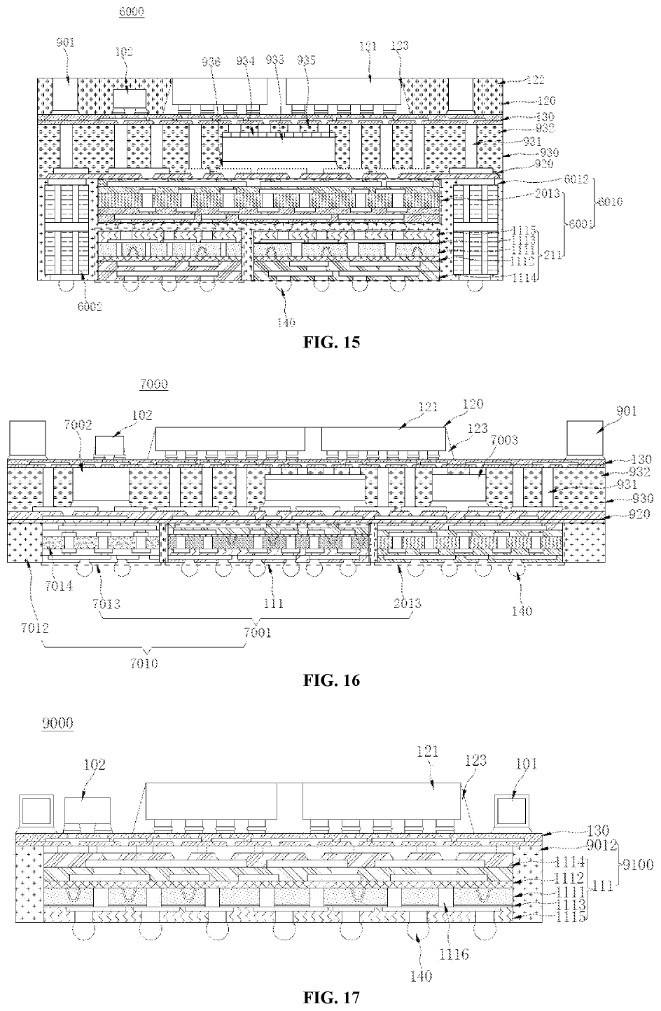

As shown in FIG. 15, a fifteenth embodiment of the present invention further provides a packaging structure 6000. The packaging structure 6000 is different from the packaging structure 3000 in the following aspects.

1) Two prefabricated interconnected silicon core stack structures 211 (refer to the description of the packaging structure 200 in FIG. 2) are disposed below the first prefabricated substrate 2013 to constitute a first prefabricated unit 6001, and the first prefabricated unit 6001 is plastic-packaged by a first plastic packaging layer 6012 to form a lower package 6010.

2) The metal bump or solder ball 140 is electrically connected to the conductive layer in the first prefabricated redistribution stack layer 1114.

3) A build-up substrate 6002 is embedded in the first plastic packaging layer 6012, and electrically connected to the second redistribution stack layer 920 and the metal bump or solder ball 140, wherein the build-up substrate 6002 may be used to realize flexible interconnection.

In this embodiment, two prefabricated interconnected silicon core stack structure 211 may have same or different functions, and are located at the bottom of the lower package 6010.

In addition, the same reference numerals in FIG. 15 and FIG. 12 indicate that same elements have similar functions, which is not further described in detail.

As shown in FIG. 16, a sixteenth embodiment of the present invention further provides a packaging structure 7000. The packaging structure 7000 is different from the packaging structure 900 in the following aspect.

A lower package 7010 includes the prefabricated interconnected silicon core stack structure 111, the first prefabricated substrate 2013 distributed horizontally at the right side of the prefabricated interconnected silicon core stack structure 111, and a third prefabricated substrate 7013 distributed horizontally at the left side of the prefabricated interconnected silicon core stack structure 111.

In this embodiment, the prefabricated interconnected silicon core stack structure 111, the first prefabricated substrate 2013 and the third prefabricated substrate 7013 are horizontally arranged side by side to constitute a second prefabricated unit 7001, and then, the second prefabricated unit 7001 is plastic-packaged by a first plastic packaging layer 7012 to form the lower package 7010.

A base material layer 7014 of the third prefabricated substrate 7013 may be different from or same as that of the first prefabricated substrate 2013. Preferably, a functional material is filled in the base material layer 7014, and the functional material includes a heat-resistant filler, a magnetic filler, and the like.

In addition, due to the horizontal and side-by-side disposal, the prefabricated interconnected silicon core stack structure 111, the first prefabricated substrate 2013 and the third prefabricated substrate 7013 may be disposed on a wafer in the same layer in a wafer-level or panel-level fan-out packaging process, and filled with different filler layers.

Further, a virtual component 7002, a silicon capacitor 7003, and the like in the interconnected chip packaging layer 930 are disposed in the same layer, and electrically connected to the first redistribution stack layer 130 and the second redistribution stack layer 920 with small line width/line spacing.

As shown in FIG, 17, a seventeenth embodiment of the present invention further provides a packaging structure 9000. The packaging structure 9000 is different from the packaging structure 100 in that, in the packaging structure 9000, the prefabricated interconnected silicon core stack structure 111 is plastic-packaged by the first plastic packaging layer 112 to form the lower package 110, and the first redistribution stack layer 130 is disposed above the lower package 110, where the chip 121 and/or the device package 121 is flip-mounted above the first redistribution stack layer 130, and electrically connected to the first redistribution stack layer 130.

An underfill material layer 123 is filled between the chip 121 and/or the device package 121 and the first redistribution stack layer 130.

Optionally, a metal block or frame 101 is disposed at the edge and/or corner of the first redistribution stack layer 130. The metal block and/or frame 101 may be a metal or silicon block coated with a metal surface, or a silicon core, which is connected to the first redistribution stack layer 130 by metal bonding or adhesive bonding, disposed above the first redistribution stack layer 130, and preferably located at the edge and/or corner of the first redistribution stack layer 13, for improving the warpage and the heat dissipation of the packaging structure 100 and shielding the electromagnetic interference.

In addition, a functional device 102 is disposed above the first redistribution stack layer 130 and electrically connected to the first redistribution stack layer 130, and the functional device 102 may be a functional device such as a capacitor or an inductor.

Optionally, a plastic packaging material may be further disposed above the first redistribution stack layer 130 to plastic-package the chip 121 and/or device package 121, the metal block or frame 101 and the functional device 102.

Other same reference numerals in FIG. 17 and FIG. 1 indicate that same elements have similar functions, which is not further described in detail.

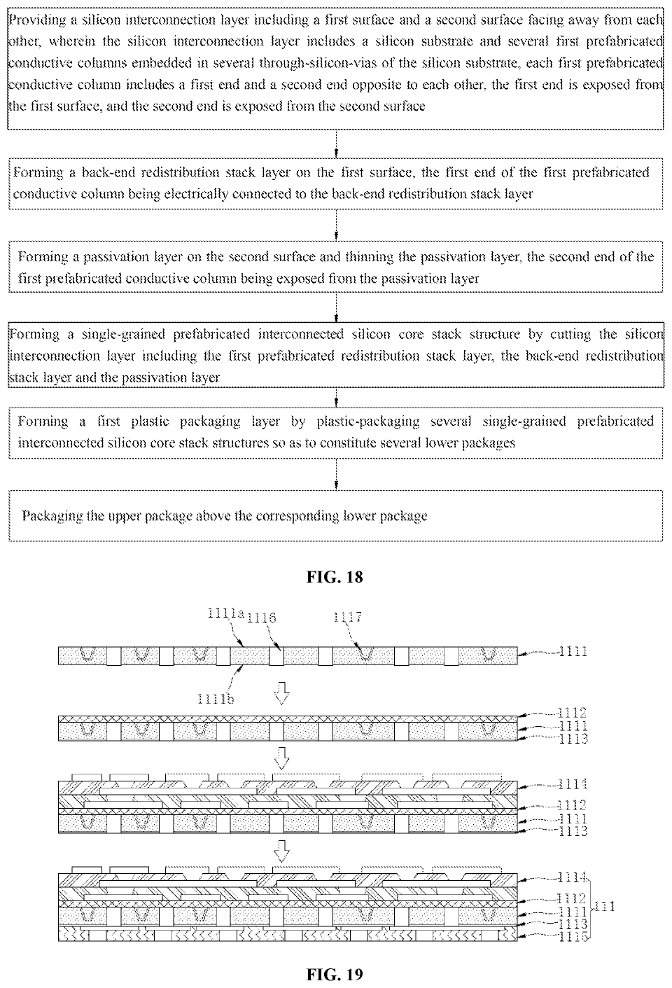

As shown in FIG. 18, the present invention further provides a manufacturing method of a packaging structure 8000. The manufacturing method includes:

providing a silicon interconnection layer, wherein the silicon interconnection layer includes a silicon substrate, the silicon substrate includes several through-silicon-vias and several first prefabricated conductive pillars embedded in the several through-silicon-vias, the silicon substrate includes a first surface and a second surface facing away from each other, each first prefabricated conductive pillar includes a first end and a second end opposite to each other, the first end is exposed from the first surface, and the second end is exposed from the second surface;

forming a back-end redistribution stack layer on the first surface, the first end of the first prefabricated conductive pillar being electrically connected to the back-end redistribution stack layer;

forming a passivation layer on the second surface and thinning the passivation layer, the second end of the first prefabricated conductive pillar being exposed from the passivation layer;

forming a first prefabricated redistribution stack layer above the back-end redistribution stack layer;

forming a single-grained prefabricated interconnected silicon core stack structure by cutting the silicon substrate including the first prefabricated redistribution stack layer, the back-end redistribution stack layer and the passivation layer;

forming a first plastic packaging layer by plastic-packaging several single-grained prefabricated interconnected silicon core stack structures so as to constitute several lower packages; and

packaging the upper package above the corresponding lower package, the upper package being located above the first prefabricated redistribution stack layer and electrically connected to the first prefabricated redistribution stack layer.

In a preferred embodiment, before the step of forming the single-grained prefabricated interconnected silicon core stack structure by cutting the silicon interconnection layer including the first prefabricated redistribution stack layer, the back-end redistribution stack layer and the passivation layer, the manufacturing method further includes the following steps:

forming a second prefabricated redistribution stack layer on the passivation layer; and forming a prefabricated chip packaging layer at a side of the second prefabricated redistribution stack layer or the first prefabricated redistribution stack layer.

In a preferred embodiment, before the step of packaging the upper package above the corresponding lower package, the manufacturing method further includes the following steps:

forming the first redistribution stack layer above the lower package; and packaging the upper package above the first redistribution stack layer.

Each step of the manufacturing method 7000 in FIG. 18 is described in detail below with the packaging structure 100 in FIG. 1 as an example.

As shown in FIG. 19, a process of manufacturing the prefabricated interconnected silicon core stack structure 111 includes the following steps.

Firstly, the silicon interconnection layer 1111 is provided. The silicon interconnection layer 1111 includes a wafer-level silicon substrate, the silicon substrate includes several through-silicon-vias in which several first prefabricated conductive pillars 1116 are embedded; the silicon substrate includes a first surface 1111a and a second surface 1111b facing away from each other; and the second surface 1111b is located in a silicon wafer body before the back-end redistribution stack layer 1112 and the first prefabricated redistribution stack layer 1114 are formed and before the first prefabricated conductive pillars 1116 are exposed, which are not depicted in the figure for simplicity. Each first prefabricated conductive pillar 1116 includes a first end and a second end opposite to each other, the first end is exposed from the first surface 1111a, and the second end is exposed from the second surface 1111b. Preferably, several trench-type capacitors 1117 are further disposed in the silicon substrate.

Next, the back-end redistribution stack layer 1112 is formed on the first surface 1111a of the wafer-level silicon substrate, and the minimum line width/line spacing of the back-end redistribution stack layer 1112 is less than 2 μm; and the passivation layer 1113 is formed on the second surface 1111b and is thinned to expose the second end of the first prefabricated conductive pillar 1116 from the passivation layer 1113.

Then, the first prefabricated redistribution stack layer 1114 is formed in a layer of the back-end redistribution stack layer 1112, and electrically connected to the back-end redistribution stack layer 1112, At this time, the silicon interconnection layer 1111, the back-end redistribution stack layer 1112, the passivation layer 1113 and the first prefabricated redistribution stack layer 1114 may constitute the prefabricated interconnected silicon core stack structure.

With continuous reference to FIG. 1, in this embodiment, the second prefabricated redistribution stack layer 1115 is manufactured at a side of the passivation layer 1113, wherein the silicon interconnection layer 1111, the back-end redistribution stack layer 1112, the passivation layer 1113, the first prefabricated redistribution stack layer 1114 and the second prefabricated redistribution stack layer 1115 jointly constitute the prefabricated interconnected silicon core stack structure 111.

Further, the single-grained prefabricated interconnected silicon core stack structure 111 is obtained by cutting the wafer-level silicon substrate (not shown).

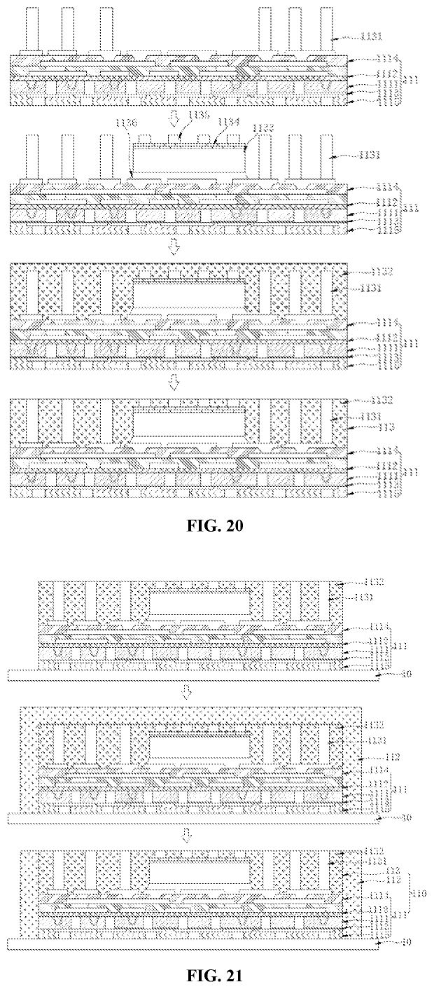

As shown in FIG. 20, a process of manufacturing the prefabricated chip packaging layer 113 on the prefabricated interconnected silicon core stack structure 111 includes the following steps.

Manufacturing the prefabricated chip packaging layer 113 on the uncut wafer-level silicon substrate with the finished prefabricated interconnected silicon core stack structure includes: forming the second prefabricated conductive pillar 1131 above the first prefabricated redistribution stack layer 1114; upright-mounting the first chip 1133 above the first prefabricated redistribution stack layer 1114 with the chip mounting layer 1136, the first chip 1133 including the prefabricated interconnected redistribution stack layer 1134 and the connection bump 1135 disposed thereon; coating the prefabricated plastic packaging material on the first prefabricated redistribution stack layer 1114, and plastic-packaging the second prefabricated conductive pillar 1131 and the first chip 1133 to form the prefabricated plastic packaging layer 1132 after the prefabricated plastic packaging material is cured; and thinning the prefabricated plastic packaging layer 1132 to expose an upper end of the second prefabricated conductive pillar 1131 from a front surface of the prefabricated plastic packaging layer 1132. At this time, the manufacturing of the prefabricated chip packaging layer 113 is finished. As another alternative solution, the manufacturing process of the first prefabricated conductive pillar 1116, the passivation layer 1113 and the second prefabricated redistribution stack layer 1115 may be performed with an optional temporary carrier plate after the prefabricated plastic packaging layer 1132 is finished, which is not depicted in the drawings for simplification.

Further, the prefabricated chip packaging layer 113 and the prefabricated interconnected silicon core stack structure 111 are both cut into the single-grained prefabricated unit, and the prefabricated unit includes the prefabricated chip packaging layer 113 and the prefabricated interconnected silicon core stack structure 111 which are stacked.

It is to be noted that, in other embodiments of the present invention, the prefabricated chip packaging layer may also be separately manufactured in the additional wafer-level or panel-level packaging technology, and cut into single grains and then bonded to the prefabricated interconnected silicon core stack structure, so as to improve the yield of the embedded first chip.

As shown in FIG. 20, a process of manufacturing the lower package 110 by plastic-packaging the single-grained prefabricated unit includes:

providing an optional temporary carrier plate or carrier band 10, and temporarily bonding several single-grained prefabricated units (only one is shown in FIG. 20) to the carrier plate 10; coating a first plastic packaging material to cover several single-grained prefabricated units so as to form the first plastic packaging layer 1132 covering several single-grained prefabricated units after the first plastic packaging material is cured; thinning the front surface of the first plastic packaging layer 1132 to expose the upper end of the second prefabricated conductive pillar 1131 and to further expose the connection bump 1135 on the first chip 1133; and at this time, constituting the lower package 110 by the first plastic packaging layer 1132 and one single-grained prefabricated unit.

As shown in FIG. 21, the first redistribution stack layer 130 is then formed above the lower package 110, and the minimum line width/line space of the first redistribution stack layer 130 is less than 5 μm.

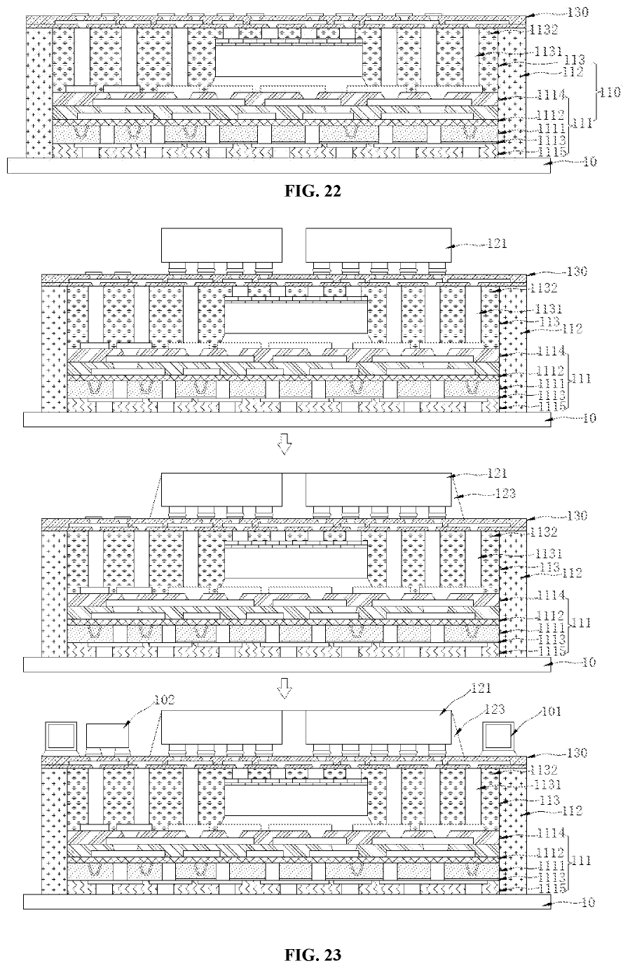

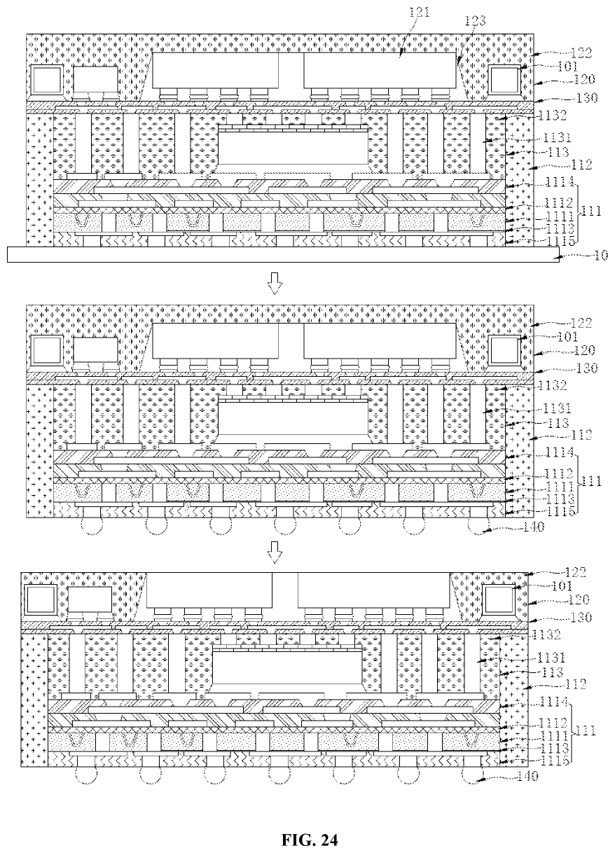

As shown in FIG. 22, 23 and FIG. 24, the manufacturing process of packaging the upper package 120 above the first redistribution stack layer 130 includes:

flip-bonding the chip 121 and/or the device package 121 above the first redistribution stack layer 130; optionally, bonding the auxiliary structure 101 and the functional device 102 to the edge and/or corner of the first redistribution stack layer 130; filling the underfill material layer 123 between the chip 121 and/or the device package 121 and the first redistribution stack layer 130; and coating a second plastic packaging material on the first redistribution stack layer 130 to cover the chip 121 and/or the device package 121 and to optionally cover the auxiliary structure 101 and the functional device 102, so as to form the second plastic packaging layer 122 after curing.

The carrier plate 10 and the lower package 110 are debonded, and the metal bump or solder ball 140 is placed at a side of the second prefabricated redistribution stack layer 1115 and electrically connected to the conductive layer of the second prefabricated redistribution stack layer 1115.

Finally, the front surface of the second plastic packaging layer 122 is thinned to expose a back surface of the chip 121 and/or device package 121.

In summary, the present invention provides a packaging structure and a manufacturing method thereof, in which the reconstituted substrate is manufactured by plastic-packaging the single-grained interconnected silicon core stack structure. Since the prefabricated interconnected silicon core stack structure may stack the prefabricated redistribution stack layer on the silicon interconnection layer, on the one hand, the prefabricated redistribution stack layer may have smaller line width/line spacing and be thinner, thereby effectively satisfying the packaging requirements of high density and small packaging volume; and on the other hand_{;} the prefabricated redistribution stack layer and more other prefabricated redistribution stack layers may be stacked on the silicon interconnection layer, thereby significantly improving the manufacturing yield of the packaging structure.

Although the present invention is described with reference to the above related embodiments, the above embodiments are only examples for implementing the present invention. Furthermore, technical features that are described above and involved in different embodiments of the present invention may be combined with each other on the precondition of no conflicts. It is to be noted that, the present invention may further include a plurality of other embodiments, and persons skilled in the art may make various corresponding changes and modifications without departing from the spirit and essence of the present invention, whereas these corresponding changes and modifications shall all be within the protection scope of the claims appended to the present invention.

What is claimed is:

1. A packaging structure, comprising:
a lower package and an upper package disposed above the lower package, the lower package and the upper package being electrically connected;
wherein the lower package comprises a prefabricated interconnected silicon core stack structure and a first plastic packaging layer surrounding the periphery of the prefabricated interconnected silicon core stack structure;
the prefabricated interconnected silicon core stack structure comprises a silicon interconnection layer, and the silicon interconnection layer comprises a first surface and a second surface facing away from each other; a back-end redistribution stack layer and a first pre-fabricated redistribution stack layer are stacked sequentially on the first surface and in electrical connection; a passivation layer is disposed on the second surface;
the silicon interconnection layer comprises a silicon substrate and a plurality of first prefabricated conductive pillars embedded in a plurality of through-silicon-vias of the silicon substrate, each of the first prefabricated conductive pillar comprises a first end and a second end opposite to each other, the first end is exposed from the first surface, and the second end is exposed from a side of the passivation layer away from the second surface; and
wherein the upper package is disposed above the first prefabricated redistribution stack layer, and is electrically connected to the first prefabricated redistribution stack layer.

2. The packaging structure according to claim 1, further comprising a back-surface redistribution stack layer disposed below the prefabricated interconnected silicon core stack structure;
wherein the back-surface redistribution stack layer is disposed at a side of the passivation layer away from the second surface, and is electrically connected to the silicon interconnection layer.

3. The packaging structure according to claim 2, wherein an edge of the back-surface redistribution stack layer protrudes from an edge of the prefabricated interconnected silicon core stack structure and extends to be stacked on the first plastic packaging layer, and/or an edge of the passivation layer protrudes from an edge of the silicon interconnection layer and extends to be stacked on the first plastic packaging layer.

4. The packaging structure according to claim 2, wherein the prefabricated interconnected silicon core stack structure further comprises a second prefabricated redistribution stack layer that is disposed at a side of the passivation layer away from the second surface and is electrically connected to the second end of each of the first prefabricated conductive pillars in the silicon interconnection layer.

5. The packaging structure according to claim 4, wherein the lower package further comprises at least one first functional block and/or at least one second functional block;
the at least one first functional block is embedded in a first base material layer of the first prefabricated redistribution stack layer; and the at least one second functional block is embedded in a second base material layer of the second prefabricated redistribution stack layer;
wherein the upper package comprises a chip and/or device package; in a thickness direction of the packaging structure, the at least one first functional block is stacked below the corresponding chip and/or device package; and the at least one second functional block is stacked below the corresponding chip and/or device package.

6. The packaging structure according to claim 4, wherein the lower package further comprises a prefabricated chip packaging layer, the prefabricated chip packaging layer comprises a plurality of second prefabricated conductive pillars, a first chip and a prefabricated plastic packaging layer, the plurality of second prefabricated conductive pillars and the first chip are embedded in the prefabricated plastic packaging layer respectively and the first plastic packaging layer further covers an outer side of the prefabricated plastic packaging layer, and the thickness of the prefabricated plastic packaging layer is 50 to 200 μm;
wherein the prefabricated chip packaging layer is disposed at a side of the first prefabricated redistribution stack layer away from the silicon interconnection layer; or the prefabricated chip packaging layer is disposed at a side of the second prefabricated redistribution stack layer away from the silicon interconnection layer.

7. The packaging structure according to claim 6, wherein the lower package further comprises a third prefabricated redistribution stack layer that is disposed between the prefabricated chip packaging layer and the back-surface redistribution stack layer and is electrically connected to the prefabricated chip packaging layer and the back-surface redistribution stack layer.

8. The packaging structure according to claim 6, wherein the prefabricated plastic packaging layer further comprises a third functional block embedded therein, and the third functional block and the first chip are horizontally disposed side by side in the prefabricated plastic packaging layer.

9. The packaging structure according to claim 1, wherein the lower package further comprises a solder mask layer disposed between the first prefabricated redistribution stack layer and the upper package, wherein the elastic modulus or tensile elongation at break of the solder mask layer is the same as or different from the elastic modulus or tensile elongation at break of a dielectric layer in the first prefabricated redistribution stack layer.

10. The packaging structure according to claim 1, further comprising a first redistribution stack layer that is disposed between the upper package and the lower package and is electrically connected to the upper package and the lower package.

11. The packaging structure according to claim 10, further comprising a second redistribution stack layer and an interconnected chip packaging layer that are disposed between the lower package and the first redistribution stack layer, wherein the second redistribution stack layer is disposed above the lower package; the interconnected chip packaging layer is disposed above the second redistribution stack layer;
the interconnected chip packaging layer comprises a plurality of conductive pillars, an interconnected chip and a second plastic packaging layer, the plurality of conductive pillars and the interconnected chip are embedded in the second plastic packaging layer respectively, two opposite ends of each conductive pillar are electrically connected to the first redistribution stack layer and the second redistribution stack layer, and the thickness of the second plastic packaging layer is 150 to 780 μm; and
the interconnected chip comprises an interconnected redistribution stack layer and a connection bump located above the interconnected redistribution stack layer, the connection bump is electrically connected to the first redistribution stack layer and the interconnected redistribution stack layer, the minimum line width/line spacing of the interconnected redistribution stack layer is less than 2 μm, and interconnected redistribution stack layer comprises at least one capacitor.

12. The packaging structure according to claim 10, further comprising an auxiliary structure disposed at an edge and/or corner of the first redistribution stack layer.

13. The packaging structure according to claim 1, wherein the silicon interconnection layer further comprises a trench-type silicon capacitor electrically connected to the back-end redistribution stack layer.

14. The packaging structure according to claim 1, wherein there are two or more prefabricated interconnected silicon core stack structures in the first plastic packaging layer, and two or more prefabricated interconnected silicon core stack structures are horizontally disposed side by side and all plastic-packaged by the first plastic packaging layer, wherein two or more prefabricated interconnected silicon core stack structures have same or different sizes.

15. The packaging structure according to claim 1, wherein the lower package further comprises a first prefabricated substrate, the first prefabricated substrate comprises a third surface and a fourth surface facing away from each other, and the prefabricated interconnected silicon core stack structure is disposed on the third surface and/or the fourth surface and electrically connected to the first prefabricated substrate respectively, wherein the prefabricated interconnected silicon core stack structure and the prefabricated substrate constitute a first prefabricated unit, and the first prefabricated unit is packaged by the first plastic packaging layer to form the lower package.

16. The packaging structure according to claim 15, wherein the lower package further comprises an underfill layer filled between the prefabricated interconnected silicon core stack structure and the first prefabricated substrate.

17. The packaging structure according to claim 1, wherein the lower package further comprises a second prefabricated substrate and/or a third prefabricated substrate, the second prefabricated substrate and/or the third prefabricated substrate are horizontally disposed side by side with respect to the prefabricated interconnected silicon core stack structure respectively to constitute a second prefabricated unit, and the second prefabricated unit is packaged by the first plastic packaging layer to form the lower package, wherein base material layers of the second prefabricated substrate and the third prefabricated substrate are made of the same or different material s.

18. A manufacturing method of a packaging structure, comprising the following steps:
providing a silicon interconnection layer comprising a first surface and a second surface facing away from each other, wherein the silicon interconnection layer comprises a silicon substrate, the silicon substrate comprises a plurality of through-silicon-vias and first prefabricated conductive pillars embedded in the plurality of through-silicon-vias, each of the first prefabricated conductive pillars comprises a first end and a second end opposite to each other, the first end is exposed from the first surface, and the second end is exposed from the second surface;
forming a back-end redistribution stack layer on the first surface, the first end of the first prefabricated conductive pillar being electrically connected to the back-end redistribution stack layer;
forming a passivation layer on the second surface and thinning the passivation layer, the second end of the first prefabricated conductive pillar being exposed from the passivation layer;
forming a first prefabricated redistribution stack layer above the back-end redistribution stack layer;
forming a single-grained prefabricated interconnected silicon core stack structure by cutting the silicon interconnection layer comprising the first prefabricated redistribution stack layer, the back-end redistribution stack layer and the passivation layer;
forming a first plastic packaging layer by plastic-packaging the plurality of single-grained prefabricated interconnected silicon core stack structures so as to constitute a plurality of lower packages; and
packaging the upper package above the corresponding lower package, the upper package being electrically connected to the first prefabricated redistribution stack layer.

19. The manufacturing method of a packaging structure according to claim 18, wherein before the step of forming the single-grained prefabricated interconnected silicon core stack structure by cutting the silicon interconnection layer comprising the first prefabricated redistribution stack layer, the back-end redistribution stack layer and the passivation layer, the manufacturing method further comprises the following steps:
forming a second prefabricated redistribution stack layer on the passivation layer; and
forming a prefabricated chip packaging layer at a side of the second prefabricated redistribution stack layer or the first prefabricated redistribution stack layer.

20. The manufacturing method of a packaging structure according to claim 18, wherein before the step of packaging the upper package above the corresponding lower package, the manufacturing method further comprises the following steps:
forming the first redistribution stack layer above the lower package; and
packaging the upper package above the first redistribution stack layer.
